(19) United States
(12) Patent Application Publication
(10) Pub. No.: US 2011/0034033 A1
(43) Pub. Date: Feb. 10, 2011

(54) Electronic Devices and Methods of Making the Same Using Solution Processing Techniques

(75) Inventors: Jonathan Halls, Cambridge (GB); Gregory Whiting, Menlo Park, CA (US)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: CAMBRIDGE DISPLAY TECHNOLOGY

(21) Appl. No.: 12/809,644

(22) PCT Filed: Dec. 17, 2008
(86) PCT No.: PCT/GB08/04141

§ 371 Date: Oct. 25, 2010

(30) Foreign Application Priority Data
Dec. 19, 2007 (GB) 0724771.1

(51) Int. Cl. H01L 21/312

(52) U.S. Cl. 438/758; 257/E21.259

(57) ABSTRACT

A method of manufacturing an electronic device, the method comprising: providing a substrate; forming a patterned layer of removable material on the substrate; depositing, using an indiscriminate deposition method, a layer of a surface energy modifying material over the substrate comprising the patterned layer of removable material; removing the removable material from the substrate thereby forming a patterned surface of the substrate with surface energy modifying material in those areas not previously covered by the removable material and no surface energy modifying material in those areas previously covered by the removable material; and depositing one or more active components from solution on the patterned surface of the substrate using an indiscriminate deposition technique whereby a patterned layer of the one or more active components is formed based on the pattern of surface energy modifying material on the substrate.

### FIELD OF INVENTION

The present invention relates to electronic devices and methods of making the same using solution processing techniques. Particular embodiments of the present invention relate to organic thin film transistors, organic optoelectronic devices, organic light emissive display devices and methods of making the same using solution processing techniques.

### BACKGROUND OF THE INVENTION

Methods of manufacturing electronic devices involving depositing active components from solution are known in the art. These methods can be broadly categorized into two main groups: indiscriminate methods in which a solution of one or more active components is indiscriminately deposited over the entire active surface of a substrate to form an unpatterned layer on the surface of the substrate; and discriminate methods in which a solution of one or more active components is selectively deposited on specific areas of the active surface of a substrate to form a patterned layer on the surface of the substrate. Examples of indiscriminate methods of depositing active components from solution include spin-coating, dip-coating, spray-coating, and flood printing. Examples of discriminate methods of depositing active components from solution include inkjet printing.

If a patterned layer comprising one or more active components is desired, which is usually the case for electronic devices, and if an indiscriminate method of depositing the active components is utilized to form an unpatterned layer, then further processing steps will be required in order to form a patterned layer. These further processing steps involve removing the active components from areas of the substrate where the active components are not required in order to form a patterned layer. Typical further processing steps of this kind include lithographic methods involving masking and etching to form the patterned layer.

If active components are deposited from solution using a discriminate method such as inkjet printing, one problem is how to contain the active components in desired areas of the substrate while the solution is drying. One solution to this problem is to provide a substrate comprising a patterned bank layer defining wells in which the active components can be deposited in solution. The wells contain the solution while it is drying such that the active components remain in the areas of the substrate defined by the wells.

The aforementioned solution processing methods have been found to be particularly useful for deposition of organic materials in solution. The organic materials may be conductive, semi-conductive, and/or opto-electrically active such that they can emit light when an electric current is passed through them or detect light by generating a current when light impinges on them. Devices which utilize these materials are known as organic electronic devices. An example is an organic thin film transistor (OTFT) which comprises an organic semiconductor (OSC). Another example is an organic light-emissive device (OLED) which comprises an organic light-emissive material. The organic light-emissive material may be formed in a patterned layer of emissive pixels in order to form an organic light emissive display. These pixels may be controlled by thin film transistors in a so-called active matrix organic light-emissive display (AMOLED). It the thin film transistors are OTFTs then the active matrix organic light-emissive display will comprise both OTFTs and OLEDs.

It has been found that in certain circumstances, organic electronic devices such as OTFTs and OLEDs have better performance characteristics if the active organic components are deposited by an indiscriminate method such as spin-coating rather than a discriminate method such as inkjet printing. One reason for this is that the film forming characteristics of layers deposited by indiscriminate methods are significantly different to the film forming characteristics of layers deposited by discriminate methods. For example, indiscriminate methods may form a film of more uniform thickness in certain circumstances. Furthermore, the molecular microstructure of the material in the film may be different, for example, the molecular order may be greater leading to a more crystalline film using indiscriminate methods which can increase the charge transporting properties of the film. Such characteristics can thus affect the functional properties of the film itself and also the performance of a device comprising the film.

In light of the above, in certain circumstances it would be advantageous to use an indiscriminate method of depositing active components when manufacturing such devices. However, the further processing steps involved in forming a patterned layer such as masking and etching may be time consuming, expensive, and can damage other components of the device under manufacture, particularly underlying layers of material. Accordingly, it would be advantageous to provide a method of manufacture which utilized an indiscriminate deposition technique but which does not require further processing steps such as masking and etching to form a patterned layer.

One such method known in the art is to treat the surface of a substrate so that the surface energy of the substrate is modified in accordance with a pattern comprising areas of high surface energy (wetting areas/hydrophilic) and areas of low surface energy (anti-wetting areas/hydrophobic). When a solution of one or more active components is deposited thereon, the solution will de-wet from the areas of low surface energy and flow into the regions of high surface energy. Thus on drying, the one or more active components will be disposed in the areas of high surface energy forming a patterned layer without requiring further processing steps. Such a technique for manufacturing organic electronic devices is described in two of the present applicant's earlier patent applications published as WO 2004/006291 and GB-A-2437328. In these earlier applications a stamping method is utilized in order to form the surface energy pattern on the substrate prior to deposition of active components from solution. Embodiments are described in which a patterned poly-dimethylsiloxane (PDMS) stamp is used. When the stamp is brought into contact with the substrate, PDMS is transferred from the stamp to the substrate forming low surface energy anti-wetting regions on those areas of the substrate which are contacted while leaving those areas which are not contacted as higher surface energy wetting regions.

It is an aim of the present invention to provide an alternative to the aforementioned stamping method.

### SUMMARY OF THE PRESENT INVENTION

According to a first aspect of the present invention there is provided a method of manufacturing an electronic device, the method comprising: providing a substrate; forming a patterned layer of removable material on the substrate; depositing, using an indiscriminate deposition method, a layer of a surface energy modifying material over the substrate comprising the patterned layer of removable material; removing the removable material from the substrate thereby forming a patterned surface of the substrate with surface energy modifying material in those areas not previously covered by the removable material and no surface energy modifying material in those areas previously covered by the removable material; and depositing one or more active components from solution on the patterned surface of the substrate using an indiscriminate deposition technique whereby a patterned layer of the one or more active components is formed based on the pattern of surface energy modifying material on the substrate.

This method is advantageous in that no discriminate deposition method is required for either of the surface energy modifying material or the solution of active components. For example, no complicated patterned stamp is required for forming the patterned layer of surface energy modifying material and no patterned well-defining layer is required for the active components. As such, it is possible to form both these layers in a quick and simple manner while achieving the film forming characteristics associated with a film deposited using an indiscriminate deposition method.

Furthermore, no damaging post-deposition treatment steps are required to form either of the patterned layer of surface energy modifying material or the patterned layer of active components. Only one post-deposition treatment step is required to form the patterned layer of surface energy modifying material, that of removing the removable material from the substrate. However, this can be done easily because the removable material is a material which is readily removable from the substrate. No post-deposition treatment steps at all are required in order to form the patterned layer of active components as this layer forms a pattern automatically as a consequence of the patterned layer of surface energy modifying material.

Further still, as only an indiscriminate deposition method is required for the surface energy modifying material, a larger range of possible surface energy modifying materials may be utilized, many of which would be unsuitable for forming a stamp as in the prior art methods previously discussed in the background section.

Preferably, the indiscriminate deposition method used to deposit the layer of surface energy modifying material is a solution processing method such as spin-coating, dip-coating, spray-coating, or flood printing. Such solution processing methods are fast and cheap. Furthermore, they are particularly good for coating large areas and/or uneven surfaces. The solution may be aqueous or organic.

For such solution processing methods, the surface energy modifying material must be solution processable. There are many such materials. Examples include silanes such as chloro- or alkoxy-silanes, for example octadecyltrichlorosilane (OTS); phosphates; thiols; and fluorine containing polymers such as Cytop (which is available from Asahi Glass). Preferably the surface energy modifying material forms a self assembled monolayer (SAM) on the substrate. It has been found that SAMs are particularly effective at forming a surface energy pattern which functions to pattern a solution of active components deposited thereon.

The surface energy modifying material may be an anti-wetting material (low surface energy/hydrophobic) or a wetting material (high surface energy/hydrophillic). If the surface energy modifying material is an anti-wetting material then the solution comprising the one or more active components will de-wet from the material and flow into areas of the substrate not covered by the anti-wetting material. As such, the patterned layer of the one or more active components will have the same pattern as the pattern of removable material which was initially formed on the substrate. Alternatively, if the surface energy modifying material is a wetting material then the solution comprising the one or more active components will flow into areas of the substrate covered by the wetting material. As such, the patterned layer of the one or more active components will have a pattern inverse to that of the pattern of removable material which was initially formed on the substrate.

If the surface energy modifying material is a wetting material, then the surface energy should be high enough to break the surface tension of the solution of one or more active components being deposited thereon such that the solution flows onto the wetting material. Similarly, the substrate should have a surface energy low enough that it does not break the surface tension of the solution in order that the solution remains on the wetting material.

Conversely, if the surface energy modifying material is an anti-wetting material, then the surface energy should be low enough that it does not break the surface tension of the solution of one or more active components being deposited thereon such that the solution de-wets from the anti-wetting material. Similarly, the substrate should have a surface energy high enough that it breaks the surface tension of the solution in order that the solution wets the substrate in the areas not covered by the anti-wetting material.

In either of the cases described above, the difference in the surface energy of the substrate material and the surface energy modifying material must be sufficient such that the solution of one or more active components deposited thereon preferentially wets onto one of the materials at the expense of the other. If the solution is fast drying (e.g. low volume or highly volatile solvent) then the wetting/de-wetting process must occur quickly. Accordingly, in this case the material of the substrate and the energy modifying material should be selected so that the difference in surface energies is large such that the wetting/de-wetting process will occur quickly. Conversely, if the solution is slow drying (e.g. high volume or low volatile solvent) then the wetting/de-wetting process can occur more slowly. Accordingly, in this case the material of the substrate and the energy modifying material may be selected so that the difference in surface energies is not so large. Preferably, a difference in the surface energy of the material of the substrate and the surface energy modifying material is at least 5 mN/m, preferably at least 10 mN/m, more preferably at least 15 mN/m.

The removable material is preferably removed using a physical rather than chemical removal step. That is, the removable material is preferably not chemically bonded to the substrate such that a chemical reaction is required to remove the material from the substrate. Examples of physical removal methods include sonification, washing, pealing, brushing, rubbing, plasma treatment, and fluid (liquid or gas) jetting such as a stream of air or inert gas. The removable material should be at least removable to the extent that it can be removed without damaging any other components on the substrate such as the layer of surface energy modifying material or underlying layers. As such, the binding energy of the removable material to the substrate should be low enough to achieve this goal while being high enough that the removable material does not separate from the substrate during the step of depositing the surface energy modifying material. Suitable binding energies will depend on the particular materials being used to form the electronic device, but preferably the binding energy will be such that the removable material is removable using adhesive tape (the so-called “tape test”). Alternatively, the removable material may be a material that can be removed by washing the substrate in a solvent in which the surface energy modifying material is insoluble.

The particular material used as the removable material in the present invention will depend on the material of the substrate on which it is disposed. The material may be organic, inorganic, a metal or an alloy. For a glass substrate, an example of a suitable removable material is a metal such as gold or aluminium which adheres very weakly to glass and is readily removed by, for example, by mechanical means such as sonicating in a solution such as toluene. Alternatively, the removable material may be a material that can be removed by dissolution. Examples of such materials are polymers, for example polyethylene or polystyrene.

The patterned layer of removable material may be formed on the substrate using a mask, preferably the same mask as used for depositing one of more other components of the electronic device. For example, an OLED electrode mask or a TFT gate mask may be used to define the pattern of the removable material on the substrate. This negates the requirement for an additional mask and also results in self-alignment of the active layers in the device.

Preferably, the one or more active components comprise a conductive or semi-conductive organic material, e.g. an organic semiconductor for an OTFT. The one or more active components may comprise a light-emissive organic material, e.g. an organic light-emissive material for an OLED. Other examples include charge injection materials and charge transporting materials. The solution of the one or more active components may be aqueous or organic.

One or more further solutions of active components may be deposited. These also wet/de-wet according to the surface energy pattern on the substrate forming a plurality of patterned layers stacked one on top of the other in wetting regions of the substrate.

### SUMMARY OF THE DRAWINGS

The present invention will now be described in further detail, by way of example only, with reference to the accompanying drawings in which:

FIG. 1 shows a general process by which a surface energy pattern is used to form patterned layers of active material on a substrate;

FIG. 2 shows a process by which a surface energy pattern is used to form patterned layers of active material on a substrate in accordance with an embodiment of the present invention;

FIG. 3 shows the basic device architecture of an organic thin film transistor; and

FIG. 4 shows the basic device architecture of an organic light emissive device.

### DETAILED DESCRIPTION OF PREFERRED EMBODIMENTS

The present invention is concerned with the patterning of layers for organic electronic devices using surface energy patterning. Specifically, the invention provides a method of producing the surface energy pattern by using a removable/sacrificial layer. Embodiments can be utilized in situations where multiple layers need to be patterned in the same pattern using solution processing, without the use of ink-jet printing.

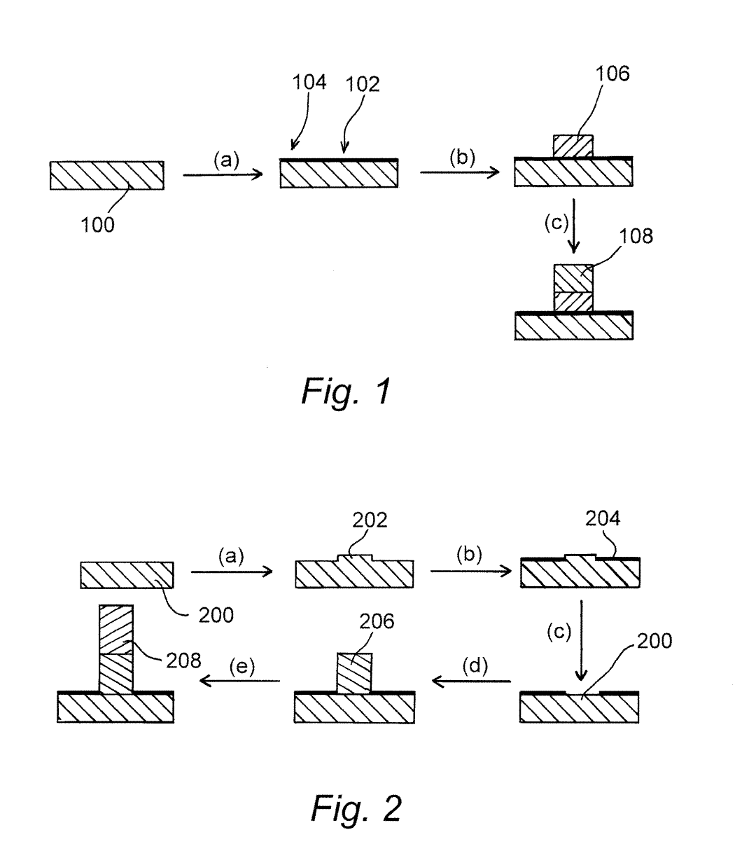

FIG. 1 shows a general process by which a surface energy pattern is used to form patterned layers of active material on a substrate 100. In step (a) the surface energy pattern is defined to form wetting 102 and anti-wetting 104 regions. In step (b) the surface energy patterned surface is coated with a first layer 106. This layer is deposited from solution and de-wets from the anti-wetting regions 104 into the wetting regions 102. In step (c) a second layer 108 is deposited from solution. Again this layer de-wets from the anti-wetting regions 104 such that it is disposed over the first layer 106.

FIG. 2 shows a process by which a surface energy pattern is formed to create patterned layers of active material on a substrate 200 in accordance with an embodiment of the present invention. In step (a) a sacrificial layer of removable material 202 is deposited on the substrate 200 in an active region. In step (b) a layer of anti-wetting material 204 is deposited over the substrate 200. In step (c) the sacrificial layer 202 is removed to expose the underlying substrate 200 thereby defining a surface energy pattern. In step (d) the surface energy patterned surface is coated with a first layer 206. This layer is deposited from solution and de-wets from the anti-wetting material 204 onto the exposed substrate 200. In step (e) a second layer 208 is deposited from solution. Again this layer de-wets from the anti-wetting material 204 such that it is disposed over the first layer 206.

A key feature of embodiments of the present invention is the use of a sacrificial layer of removable material for forming the surface energy pattern. The sacrificial layer (e.g. metal, organic, etc) is deposited (e.g. by evaporation, spin-coating, etc) onto a substrate (e.g. glass, etc) and defined into a pattern (e.g. by masked evaporation, photolithography, etc) that subsequently deposited films will eventually be confined to. After the sacrificial layer is deposited, the material (e.g. SAMs, etc) which will define the area that the films are not to be present (anti-wetting region) can then be deposited (e.g. by spin-coating, etc). The sacrificial layer can then be removed (e.g. by sonication, solvent lift-off, etc) leaving the native substrate surface in the region where the film will eventually be, surrounded by an anti-wetting region. Following this, the desired material (e.g. OSC, etc) can then be deposited (e.g. by spin-coating, dip-coating, etc), and will de-wet into the desired pattern. As long as the anti-wetting layer is stable (and the first layer is sufficiently wetting), it is possible for further layers to de-wet into the desired pattern forming a patterned stacked structure. This method allows patterns to be formed using methods such as spin-coating, which are often more simple than patterning methods such as ink-jet printing. Also, in some cases deposition methods such as spin-coating can lead to improved device performance when compared with printing.

An experiment has been carried out using this method for fabrication of OTFTs. In the experiment the gate evaporation mask of the OTFT was used to define the sacrificial layer, as this is what defines the active region of the OTFT (for OLEDs the cathode mask could be used). Gold was used as the sacrificial layer which was formed by thermal evaporation of gold through the gate mask onto a clean, plain glass substrate. The use of gold as a sacrificial layer relies on the fact that gold adheres very poorly to clean glass. Following gold evaporation, the substrate was exposed to a 10 minute, 550 W oxygen plasma treatment to prepare for anti-wetting SAM deposition. The clean, hydrophilic substrate was then immersed in a dilute (˜1 mM) solution of octadecyltrichlorosilane (OTS) in toluene for about 1 hour. The OTS bound to the glass surface generating an anti-wetting SAM (contact angle of ˜100° for water). Following OTS deposition, the substrate was sonicated in a toluene solution to remove the poorly adhered gold, but leave the anti-wetting SAM. This then gave the desired starting substrate, with bare gold defining the wetting region and the OTS monolayer defining the anti-wetting region. OSC was then spun onto the surface and was observed to de-wet into the desired pattern. Other layers of the OTFT are then deposited.

The aforementioned description is for a top-gate OTFT in which the organic semiconductor is deposited directly on the glass substrate. The substrate may comprise a number of active layers which are deposited prior to performing the method of the present invention. For example, patterned electrode layers may be provided on the substrate. For top-gate OTFTs, the source and drain electrodes are disposed on the substrate prior to solution processing of the organic semi-conductor. For a bottom-gate OTFT the substrate comprises a gate electrode layer, a gate dielectric layer, and layer of source and drain electrodes. The method of the present invention may be applied thereover in order to pattern the organic semi-conductor into channel regions on the gate dielectric between the source and drain electrodes. For an OLED, the substrate may comprise a patterned anode layer, e.g. ITO.

Materials and processes suitable for forming an OTFT in accordance with embodiments of the present invention are discussed in further detail below.

### General Device Architecture

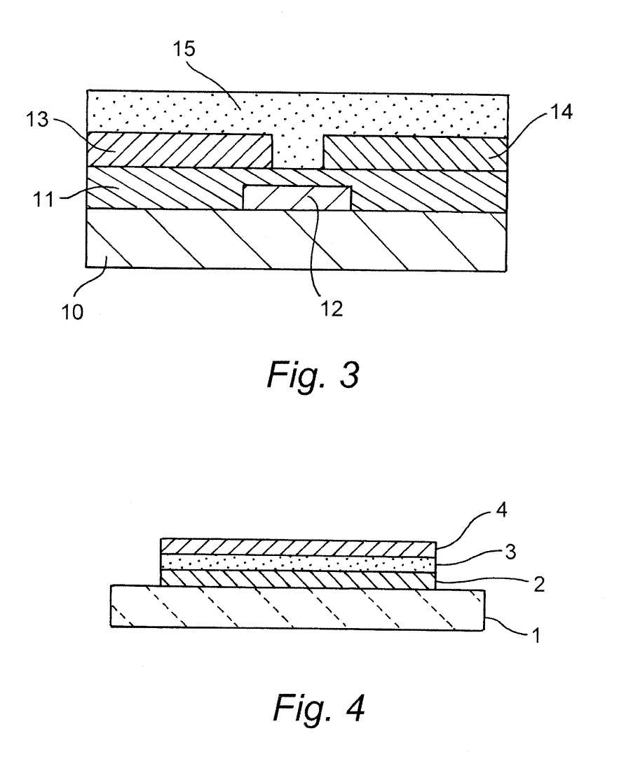

With reference to FIG. 3, the general architecture of a bottom-gate organic thin film transistor (OTFT) comprises a gate electrode 12 deposited on a substrate 10. An insulating layer 11 of dielectric material is deposited over the gate electrode and source and drain electrodes 13, 14 are deposited over the insulating layer of dielectric material. The source and drain electrodes are spaced apart to define a channel region therebetween located over the gate electrode. An organic semiconductor (OSC) material 15 is deposited in the channel region for connecting the source and drain electrodes. The OSC layer may extend at least partially over the source and drain electrodes.

Alternatively, it is known to provide a gate electrode at the top of an organic thin film transistor to form a so-called top-gate organic thin film transistor. In such an architecture source and drain electrodes are deposited on a substrate and spaced apart to define a channel region therebetween. A layer of an organic semiconductor material is deposited in the channel region to connect the source and drain electrodes and may extend at least partially over the source and drain electrodes. An insulating layer of dielectric material is deposited over the organic semiconductor material and may also extend at least partially over the source and drain electrodes. A gate electrode is deposited over the insulating layer and located over the channel region.

The organic semiconductor material may be classed as p-type or n-type. In a p-type material, electric charges are carried mainly in the form of electron deficiencies called holes. In an n-type material, the charge carriers are primarily electrons. Preferably, the organic thin film transistor is of a p-type. Ambipolar devices, i.e. devices that can function as n- or p-type, are also known.

### Substrate

The substrate may be rigid or flexible. Rigid substrates may be selected from glass or silicon and flexible substrates may comprise thin glass or plastics such as poly(ethylene-terephthalate) (PET), poly(ethylene-naphthalate) PEN, polycarbonate and polyimide.

### Organic Semiconductor Materials

The organic semiconductive material may be made solution processable through the use of a suitable solvent. Exemplary solvents include: mono- or poly-alkylbenzenes such as toluene and xylene; tetralin; and chloroform. Such materials may be deposited and patterned using the method of the present invention.

Preferred organic semiconductor materials include: small molecules such as optionally substituted pentacene; optionally substituted polymers such as polyarylenes, in particular polyfluorenes and polythiophenes; and oligomers. Blends of materials, including blends of different material types (e.g. a polymer and small molecule blend) may be used.

### Source and Drain Electrodes

For a p-channel OTFT, preferably the source and drain electrodes comprise a high workfunction material, preferably a metal, with a workfunction of greater than 3.5 eV, for example gold, platinum, palladium, molybdenum, tungsten, or chromium. More preferably, the metal has a workfunction in the range of from 4.5 to 5.5 eV. Other suitable compounds, alloys and oxides such as molybdenum trioxide and indium tin oxide may also be used. The source and drain electrodes may be deposited by thermal evaporation and patterned using standard photolithography and lift off techniques as are known in the art.

Alternatively, conductive polymers may be deposited as the source and drain electrodes. An example of such a conductive polymers is poly(ethylene dioxythiophene) (PEDOT) although other conductive polymers are known in the art. Such conductive polymers may be deposited and patterned using the method of the present invention.

For an n-channel OTFT, preferably the source and drain electrodes comprise a material, for example a metal, having a workfunction of less than 3.5 eV such as calcium or barium or a thin layer of metal compound, in particular an oxide or fluoride of an alkali or alkali earth metal for example lithium fluoride, barium fluoride and barium oxide. Alternatively, conductive polymers may be deposited as the source and drain electrodes. Such conductive polymers may be deposited and patterned using the method of the present invention.

The source and drain electrodes are preferably formed from the same material for ease of manufacture. However, it will be appreciated that the source and drain electrodes may be formed of different materials for optimisation of charge injection and extraction respectively.

The length of the channel defined between the source and drain electrodes may be up to 500 microns, but preferably the length is less than 200 microns, more preferably less than 100 microns, most preferably less than 20 microns.

### Gate Electrode

The gate electrode can be selected from a wide range of conducting materials for example a metal (e.g. gold) or metal compound (e.g. indium tin oxide). Alternatively, conductive polymers may be deposited as the gate electrode. Such conductive polymers may be deposited and patterned using the method of the present invention.

Thicknesses of the gate electrode, source and drain electrodes may be in the region of 5-200 nm, although typically 50 nm as measured by Atomic Force Microscopy (AFM), for example.

### Gate Dielectric

The gate dielectric comprises a dielectric material selected from insulating materials having a high resistivity. The dielectric constant, k, of the dielectric is typically around 2-3 although materials with a high value of k are desirable because the capacitance that is achievable for an OTFT is directly proportional to k, and the drain current I_{D} is directly proportional to the capacitance. Thus, in order to achieve high drain currents with low operational voltages, OTFTs with thin dielectric layers in the channel region are preferred.

The dielectric material may be organic or inorganic. Preferred inorganic materials include Si0₂, SiNx and spin-on-glass (SOG). Preferred organic materials are generally polymers and include insulating polymers such as poly vinylalcohol (PVA), polyvinylpyrrolidine (PVP), acrylates such as polymethylmethacrylate (PMMA) and benzocyclobutanes (BCBs) available from Dow Corning. The insulating layer may be formed from a blend of materials or comprise a multi-layered structure.

The dielectric material may be deposited by thermal evaporation, vacuum processing or lamination techniques as are known in the art. Alternatively, the dielectric material may be deposited and patterned using the method of the present invention.

If the dielectric material is deposited from solution onto the organic semiconductor, it should not result in dissolution of the organic semiconductor. Likewise, the dielectric material should not be dissolved if the organic semiconductor is deposited onto it from solution. Techniques to avoid such dissolution include: use of orthogonal solvents, i.e. use of a solvent for deposition of the uppermost layer that does not dissolve the underlying layer; and crosslinking of the underlying layer.

The thickness of the gate dielectric layer is preferably less than 2 micrometres, more preferably less than 500 nm.

### Further Layers

Other layers may be included in the device architecture. For example, a self assembled monolayer (SAM) may be deposited on the gate, source or drain electrodes, substrate, insulating layer and organic semiconductor material to promote crystallity, reduce contact resistance, repair surface characteristics and promote adhesion where required. In particular, the dielectric surface in the channel region may be provided with a monolayer comprising a binding region and an organic region to improve device performance, e.g. by improving the organic semiconductor's morphology (in particular polymer alignment and crystallinity) and covering charge traps, in particular for a high k dielectric surface. Exemplary materials for such a monolayer include chloro- or alkoxy-silanes with long alkyl chains, e.g. octadecyltrichlorosilane. Similarly, the source and drain electrodes may be provided with a SAM to improve the contact between the organic semiconductor and the electrodes. For example, gold SD electrodes may be provided with a SAM comprising a thiol binding group and a group for improving the contact which may be a group having a high dipole moment; a dopant; or a conjugated moiety. Such layers may be deposited and patterned using the method of the present invention.

Materials and processes suitable for forming an OLED in accordance with embodiments of the present invention are discussed in further detail below.

### General Device Architecture

With reference to FIG. 4, the architecture of an electroluminescent device according to the invention comprises a transparent glass or plastic substrate 1, an anode 2 and a cathode 4. An electroluminescent layer 3 is provided between anode 2 and cathode 4.

In a practical device, at least one of the electrodes is semi-transparent in order that light may be absorbed (in the case of a photoresponsive device) or emitted (in the case of an OLED). Where the anode is transparent, it typically comprises indium tin oxide.

### Charge Transport Layers

Further layers may be located between anode and cathode, such as charge transporting, charge injecting or charge blocking layers.

In particular, it is desirable to provide a conductive hole injection layer, which may be formed from a conductive organic or inorganic material provided between the anode and the electroluminescent layer to assist hole injection from the anode into the layer or layers of semiconducting polymer. Examples of doped organic hole injection materials include doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and poly(thienothiophene). Examples of conductive inorganic materials include transition metal oxides such as VOx MoOx and RuOx as disclosed in Journal of Physics D: Applied Physics (1996), 29(11), 2750-2753.

If present, a hole transporting layer located between anode and electroluminescent layer preferably has a HOMO level of less than or equal to 5.5 eV, more preferably around 4.8-5.5 eV. HOMO levels may be measured by cyclic voltammetry, for example.

If present, an electron transporting layer located between electroluminescent layer 3 and cathode 4 preferably has a LUMO level of around 3-3.5 eV.

### Electroluminescent Layer

The electroluminescent layer may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

The electroluminescent layer may be patterned or unpatterned. A device comprising an unpatterned layer may be used an illumination source, for example. A white light emitting device is particularly suitable for this purpose. A device comprising a patterned layer may be, for example, an active matrix display or a passive matrix display. The patterned layer may be formed in accordance with the method of the present invention.

In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Suitable materials for use in electroluminescent layer include small molecule, polymeric and dendrimeric materials, and compositions thereof. Suitable electroluminescent polymers include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers include electroluminescent metal complexes bearing dendrimeric groups as disclosed in, for example, WO 02/066552.

### Electrodes

The anode is selected from materials that have a workfunction allowing injection of holes into the electroluminescent layer. Where the anode is transparent, it typically comprises indium tin oxide. Otherwise a high work function metal or alloy can be used.

The cathode is selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode will comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Optical devices tend to be sensitive to moisture and oxygen. Accordingly, the substrate preferably has good barrier properties for prevention of ingress of moisture and oxygen into the device. The substrate is commonly glass. However, alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is preferably encapsulated with an encapsulant to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

### Solution Processing

A single component or a plurality of components may be deposited from solution. The components may be polymers, dendrimers, oligomers, or small molecules with solubilising groups. The solution may be aqueous or organic. Examples of suitable solvents for polyarylenes, in particular polyfluorenes, include mono- or poly-alkylbenzenes such as toluene and xylene. The components can be deposited and patterned into a layer using the method of the present invention. For example, the method of the present invention can be used to form a stack of layers comprising a hole injection layer, a hole transport layer and an electroluminescent layer, the stack of layers being disposed between an anode and a cathode in order to form the OLED.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

In addition to the OTFTs and OLEDs discussed above, it is envisaged that the method of the present invention may be utilized in other electronic devices in which it is desired to form a patterned layer of electrically active material using solution processing techniques.

While this invention has been particularly shown and described with reference to preferred embodiments thereof, it will be understood by those skilled in the art that various changes in form and detail may be made therein without departing from the scope of the invention as defined by the appended claims.

1. A method of manufacturing an electronic device, the method comprising:
providing a substrate;
forming a patterned layer of removable material on the substrate;
depositing, using an indiscriminate deposition method, a layer of a surface energy modifying material over the substrate comprising the patterned layer of removable material;
removing the removable material from the substrate to form a patterned surface of the substrate with surface energy modifying material in those areas not previously covered by the removable material and no surface energy modifying material in those areas previously covered by the removable material; and
depositing one or more active components from solution on the patterned surface of the substrate using an indiscriminate deposition technique to form a patterned layer of the one or more active components based on the pattern of surface energy modifying material on the substrate.

2. A method according to claim 1, wherein the indiscriminate deposition method used to deposit the layer of surface energy modifying material is a solution processing method.

3. A method according to claim 2, wherein the solution processing method is a method selected from the group consisting of spin-coating, dip-coating, spray-coating, and flood printing.

4. A method according claim 2, wherein the solution processing method uses a solution which is aqueous or organic.

5. A method according to claim 1, wherein the surface energy modifying material is a self assembled monolayer (SAM) or a fluorine containing polymer.

6. A method according to claim 1, wherein the surface energy modifying material is one of an anti-wetting material and a wetting material.

7. A method according to claim 1, wherein the difference in the surface energy of the material of the substrate and the surface energy modifying material is at least 5 mN/m.

8. A method according to claim 1, comprising removing the removable material using a physical removal process.

9. A method according to claim 8, wherein the physical removal processes is a process selected from the group consisting of sonification, washing, pealing, brushing, rubbing, plasma treatment, and fluid jetting.

10. A method according to claim 1, wherein the removable material is a material selected from the group consisting of organic materials, inorganic materials, metals, and alloys.

11. A method according to claim 10, wherein the removable material is selected from the group consisting of gold, aluminum, and polymers.

12. A method according to claim 1, wherein the substrate material is a material selected from the group consisting of organic materials, inorganic materials, metals, and alloys.

13. A method according to claim 12, wherein the substrate is selected from the group consisting of glass, silicon wafers, indium tin oxide (ITO), and plastic.

14. A method according to claim 1, comprising forming the patterned layer of removable material on the substrate using a mask.

15. A method according to claim 14, comprising using the mask to pattern at least one component of the electronic device in addition to the patterned layer of removable material.

16. A method according to claim 15, wherein the mask is one of an organic light-emissive device electrode mask and an organic thin film transistor gate mask.

17. A method according to claim 1, wherein the one or more active components comprise a conductive or semi-conductive organic material.

18. A method according to claim 17, wherein the one or more active components comprise at least one of an organic charge injecting material, an organic charge transporting material, and an organic light-emissive material.

19. A method according to claim 1, wherein the solution of the one or more active components is aqueous.

20. A method according to claim 1, comprising depositing one or more further solutions of active components and wet/de-wet according to the surface energy pattern on the substrate forming a plurality of patterned layers stacked one on top of the other in wetting regions of the substrate.

21. A method according to claim 1, wherein the difference in the surface energy of the material of the substrate and the surface energy modifying material is at least 10 mN/m.

22. A method according to claim 1, wherein the difference in the surface energy of the material of the substrate and the surface energy modifying material is at least 15 mN/m.

23. A method according to claim 1, wherein the solution of the one or more active components is organic.
